(19) United States
(12) Patent Application Publication
(10) Pub. No.: US 2025/0374593 A1
(43) Pub. Date: Dec. 4, 2025

(54) FIELD EFFECT TRANSISTOR HAVING A TRENCH GATE STRUCTURE

(71) Applicant: Infineon Technologies AG, Neubiberg (DE)

(72) Inventors: Andreas Meiser, Sauerlach (DE); Till Schlösser, München (DE); Chi Dong Nguyen, Muenchen (DE)

(21) Appl. No.: 19/214,770

(22) Filed: May 21, 2025

(30) Foreign Application Priority Data
Jun. 4, 2024 (DE) 102024205136.5

(51) Int. Cl. H10D 30/65; H10D 62/10; H10D 64/00; H10D 64/27; H10D 64/66

(52) U.S. Cl. CPC H10D 30/658; H10D 30/655; H10D 62/124; H10D 64/117; H10D 64/518; H10D 64/661

(57) ABSTRACT

A field effect transistor (FET) is proposed. The FET includes a transistor cell in a semiconductor substrate having a first surface. The transistor cell includes a source region at the first surface of the semiconductor substrate, a drain region spaced from the source region along a first lateral direction, and a trench gate structure arranged, along the first lateral direction, between the source region and the drain region. The trench gate structure includes a trench gate dielectric and a trench gate electrode. The transistor cell further includes a trench field structure arranged, along the first lateral direction, between the trench gate structure and the drain region. A top side of a first portion of the trench gate electrode is arranged below the first surface at a vertical distance from the first surface.

### TECHNICAL FIELD

The present disclosure is related to a semiconductor device, in particular to a field effect transistor, FET, comprising a trench gate structure.

### BACKGROUND

Technology development of new generations of semiconductor devices, e.g. field effect transistors (FETs), aims at improving electric device characteristics and reducing costs by shrinking device geometries. Although costs may be reduced by shrinking device geometries, a variety of tradeoffs and challenges has to be met when increasing device functionalities per unit area. For example, a trade-off between area-specific on-state resistance, RₒₙxA and reliability requirements influenced by, for example, avalanche breakdown behavior or parasitic device behavior requires design optimization.

Thus, there is a need for an improved field effect transistor.

### SUMMARY

An example of the present disclosure relates to a field effect transistor, FET. The FET includes a transistor cell in a semiconductor substrate having a first surface. The transistor cell includes a source region at the first surface of the semiconductor substrate. The transistor cell further includes a drain region spaced from the source region along a first lateral direction. The transistor cell further includes a trench gate structure arranged, along the first lateral direction, between the source region and the drain region. The trench gate structure includes a trench gate dielectric and a trench gate electrode. The transistor cell further includes a trench field structure arranged, along the first lateral direction, between the trench gate structure and the drain region. A top side of a first portion of the trench gate electrode is arranged below the first surface at a vertical distance from the first surface.

Another example of the present disclosure relates to a field effect transistor, FET. The FET includes a transistor cell in a semiconductor substrate having a first surface. The transistor cell includes a source region at the first surface of the semiconductor substrate. The transistor cell further includes a drain region spaced from the source region along a first lateral direction. The transistor cell further includes a trench gate structure arranged, along the first lateral direction, between the source region and the drain region. The transistor cell includes a trench field structure arranged, along the first lateral direction, between the trench gate structure and the drain region. The trench field structure includes a trench field dielectric and a trench gate electrode. A top side of a first portion of the trench field electrode is arranged below the first surface at a vertical distance from the first surface.

Those skilled in the art will recognize additional features and advantages upon reading the following detailed description, and upon viewing the accompanying drawings.

### BRIEF DESCRIPTION OF THE DRAWINGS

The accompanying drawings are included to provide a further understanding of the embodiments and are incorporated in and constitute a part of this specification. The drawings illustrate examples of semiconductor devices and together with the description serve to explain principles of the examples. Further examples are described in the following detailed description and the claims.

FIG. 1 is a schematic top view for illustrating a configuration example of a FET including a trench gate structure and a trench field structure.

FIG. 2A is an exemplary cross-sectional view along line a-a′ of the FET illustrated in FIG. 1.

FIG. 2B is an exemplary cross-sectional view along line A-A′ of the FET illustrated in FIG. 1.

FIG. 2C is an exemplary cross-sectional view along line B-B′ of the FET illustrated in FIG. 1.

FIG. 3A is a further exemplary cross-sectional view along line a-a′ of the FET illustrated in FIG. 1.

FIG. 3B is an exemplary cross-sectional view along line D-D′ of the FET illustrated in FIG. 1.

FIG. 3C is an exemplary cross-sectional view along line C-C′ of the FET illustrated in FIG. 1.

FIG. 4 is a further exemplary cross-sectional view along line a-a′ of the FET illustrated in FIG. 1.

### DETAILED DESCRIPTION

In the following detailed description, reference is made to the accompanying drawings, which form a part hereof and in which are shown by way of illustrations specific examples of FETs. It is to be understood that other examples may be utilized and structural or logical changes may be made without departing from the scope of the present disclosure. For example, features illustrated or described for one example can be used in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” may describe a permanent low-resistive connection between electrically connected elements, for example a direct contact between the concerned elements or a low-resistive connection via a metal and/or heavily doped semiconductor material. The term “electrically coupled” may include that one or more intervening element(s) adapted for signal and/or power transmission may be connected between the electrically coupled elements, for example, elements that are controllable to temporarily provide a low-resistive connection in a first state and a high-resistive electric decoupling in a second state. An ohmic contact is a non-rectifying electrical junction.

Ranges given for physical dimensions may include the boundary values. For example, a range for a parameter y from a to b reads as a≤y≤b. The same holds for ranges with one boundary value like “at most” and “at least”.

The terms “on” and “over” are not to be construed as meaning only “directly on” and “directly over”. Rather, if one element is positioned “on” or “over” another element (e.g., a layer is “on” or “over” another layer or “on” or “over” a substrate), a further component (e.g., a further layer) may be positioned between the two elements (e.g., a further layer may be positioned between a layer and a substrate if the layer is “on” or “over” said substrate).

An example of the present disclosure relates to a field effect transistor, FET. The FET includes a transistor cell in a semiconductor substrate having a first surface. The transistor cell includes a source region at the first surface of the semiconductor substrate. The transistor cell further includes a drain region spaced from the source region along a first lateral direction. The transistor cell further includes a trench gate structure arranged, along the first lateral direction, between the source region and the drain region. The trench gate structure includes a trench gate dielectric and a trench gate electrode. The transistor cell further includes a trench field structure arranged, along the first lateral direction, between the trench gate structure and the drain region. A top side of a first portion of the trench gate electrode may be arranged below the first surface at a vertical distance from the first surface.

The source region and the drain region or part thereof may be of an n-type. In this case, the FET may be an n-channel FET, for example. In some further examples, the source region and the drain region may be of a p-type. In this case, the FET may be a p-channel FET, for example.

For example, the FET may be a lateral FET. In a lateral FET, a load current flow direction is a lateral direction, e.g. the first lateral direction, and the source region and the drain region are spaced from each other along the first lateral direction. For example, the lateral FET may be a lateral trench FET such as a lateral trench metal oxide semiconductor field effect transistor, lateral trench MOSFET. In the trench gate structure, the trench gate dielectric may line sidewalls and a bottom side of a trench and may electrically isolate a trench gate electrode from a surrounding part of the semiconductor substrate. In the lateral trench FET, a channel current may flow along the first lateral direction at opposite sidewalls and along a bottom side of the trench gate structure, for example.

For example, the FET may be implemented monolithically using a mixed technology. Such mixed technologies can be used, for example, to form analog circuit blocks in a chip by the bipolar devices included in this technology for providing interfaces to digital systems, and to form digital circuit blocks by the complementary metal-oxide-semiconductor (CMOS) devices included in this technology for providing signal processing, and to form low-, medium- or high-voltage or power blocks by field effect transistors included in this technology. Such mixed technologies are known, for example, as bipolar CMOS-DMOS, BCD technologies or smart power technologies, SPT, and are used in a variety of application areas in the field of e.g. lighting, motor control, automotive electronics, power management for mobile devices, audio amplifiers, power supply, hard disks, printers. The FET may be part of a BCD or Smart Power chip in one of the above application fields, for example.

The semiconductor substrate may be based on various semiconductor materials, for example silicon (Si), silicon-on-insulator (SOI), silicon-sapphire (SOS), silicon-germanium, germanium, gallium arsenide, silicon carbide, gallium nitride, or other compound semiconductor materials. The semiconductor substrate may be based on a semiconductor base substrate, for example a semiconductor wafer and may include one or more epitaxial layers deposited thereon and/or may be back-thinned.

For realizing a desired current carrying capacity, the FET may be designed by a plurality of the transistor cells that are parallel-connected. The parallel-connected transistor cells may, for example, be transistor cells formed in the shape of a strip or a strip segment. Of course, the transistor cells can also have any other shape, e.g. circular, elliptical, polygonal such as hexagonal or octahedral. The transistor cells may be arranged in a transistor cell area of the semiconductor substrate. The transistor cell area may be an active area where the source region of the FET and the drain region of the FET are arranged opposite to one another along the first lateral direction. In the active area, a load current may enter or exit the semiconductor substrate of the FET, e.g. via contact plugs on the first surface and/or second surface of the semiconductor substrate.

The first surface may be a front surface or a top surface of the semiconductor substrate, and the second surface may be a back surface or a rear surface of the semiconductor substrate, for example. The semiconductor substrate may be attached to a lead frame via the second surface, for example. Over the first surface and/or second surface of the semiconductor substrate, bond pads may be arranged and bond wires may be bonded on the bond pads, for example.

The source region and a body contact region may be electrically connected to a source electrode. The source electrode may be part of a wiring area over the first surface of the semiconductor substrate, for example. The wiring area may include one or more than one, e.g. two, three, four or even more wiring levels. Each wiring level may be formed by a single one or a stack of conductive layers, e.g. metal layer(s). The wiring levels may be lithographically patterned, for example. Between stacked wiring levels, an interlayer dielectric structure may be arranged. Contact plug(s) or contact line(s) may be formed in openings in the interlayer dielectric structure to electrically connect parts, e.g. metal lines or contact areas, of different wiring levels to one another. The source electrode may be formed by one or more elements of the wiring area. Likewise, the FET may further include a drain electrode. Also the drain electrode may be formed by one or more elements of the wiring area over the first surface. For example, the source electrode and the drain electrode may include separate parts of a patterned first wiring level, e.g. a first metal layer. In some examples, the drain electrode may also be formed over the second surface of the semiconductor substrate. In this case, a drain region of the FET may be electrically connected to the drain electrode by a through contact or trench contact extending at least partly through the semiconductor substrate.

The trench gate dielectric of the trench gate structure electrically isolates the trench gate electrode from a surrounding part of the semiconductor substrate, for example. For example, the trench gate dielectric may be an insulating material such as an oxide, e.g., SiO₂, a nitride, e.g., Si₃N₄, a high-k dielectric, or a low-k dielectric, or any combination thereof. For example, the trench gate dielectric may be formed as a thermal oxide. The trench gate electrode may be formed of one or more conductive materials, e.g. metal, metal silicide, metal compound, highly doped semiconductor material such as highly doped polycrystalline silicon. For example, the trench gate electrode may be a single layer, e.g. a highly doped polycrystalline layer, or a stack of layers. For example, the source region may adjoin a first sidewall of the trench gate structure. A drift region of the first conductivity type may be arranged, along the first lateral direction, between the trench gate structure and the drain region. The drift region may adjoin to a second sidewall of the trench gate structure. The second sidewall may be opposite to the first sidewall along the first lateral direction.

The trench field structure is arranged, along the first lateral direction, between the trench gate structure and the drain region. The trench gate structure may be spaced from the trench field structure along the first lateral direction. For example, a width (e.g. extent along a second lateral direction that may be perpendicular to the first lateral direction) of the trench field plate structure may be larger, e.g. by more than 20% and by less than 200%, than a width of the trench gate structure. For example, in a transistor cell area, a pitch of arrangement of the trench field structures along the second lateral direction may be equal to a pitch of arrangement of the trench gate structures along the second lateral direction. The trench field plate and the trench gate structures may or may not be offset from each other along the second lateral direction, e.g. offset by half of the pitch.

Similar to the trench gate dielectric, the trench field dielectric electrically isolates the trench field electrode from a surrounding part of the semiconductor substrate, for example. The trench field dielectric may have a larger thickness than the trench gate dielectric, for example. For example, the trench field dielectric may be an insulating material such as an oxide, e.g., SiO₂, a nitride, e.g., Si₃N₄, a high-k dielectric, or a low-k dielectric, or any combination thereof. For example, the trench field dielectric may be formed as or include a thermal oxide and/or a deposited and annealed oxide. The trench field electrode may be formed of one or more conductive materials, e.g. metal, metal silicide, metal compound, highly doped semiconductor material such as highly doped polycrystalline silicon. For example, the trench field electrode may be a single layer, e.g. a highly doped polycrystalline layer, or a stack of layers. For example, the trench gate electrode and the trench field electrode may be made of the same material or combination of materials. Provision of the trench field structure may allow for a further reduction of the RₒₙxA.

The top side of a first portion of the trench gate electrode that is arranged below the first surface at a vertical distance from the first surface may form a step with a second portion of the trench gate electrode, for example. The vertical distance to the first surface may refer to a vertical level at the first surface where an interface between a contact, e.g. contact plug or contact line, and the source region is located, for example.

By arranging the first portion of the trench gate electrode below the first surface, device reliability may be improved by suppressing or avoiding undesired generation of an inversion channel at the corner of the trench gate structure. Furthermore, a leakage current caused by the inversion channel may be avoided or at least reduced. The inversion channel at the corner may have a smaller threshold voltage compared to the device channel at the sidewall and the corruption of the current voltage characteristic by turn-on of the channel at the corner may thus be suppressed or avoided when arranging the first portion of the trench gate electrode below the first surface.

For example, the vertical distance of the first portion of the trench gate electrode from the first surface may have a value in a range from 50 nm to 500 nm. The value range may allow for a beneficial suppression of channel turn-on in the corners of the trench gate structure, for example.

For example, the trench gate dielectric may adjoin the first portion of the trench gate electrode along the first lateral direction. The first lateral direction may be directed from the source region to the drain region. Thus, the first portion of the trench gate electrode may be arranged outward at a side toward the source region, for example. This exemplary arrangement of the first portion may allow for a beneficial suppression of channel turn-on in the corners of the trench gate structure at a side of the source region, for example.

For example, a second portion of the trench gate electrode may vertically extend at least up to the first surface of the semiconductor substrate and may be electrically connected to a gate interconnection line extending along a second lateral direction. The second lateral direction may be perpendicular to the first lateral direction. The second lateral direction may be a lateral direction along which a device width is measured. For example, the second portion may include a middle portion of the trench gate electrode along the first lateral direction, for example.

For example, the second portion of the trench gate electrode may have a lateral distance, along the first lateral direction, from the source region. The lateral distance may have a value in a range from 100 nm to 500 nm. The value range may allow for a beneficial suppression of channel turn-on in the corners of the trench gate structure, for example.

For example, materials of the trench gate electrode and the gate interconnection line may include doped polycrystalline silicon. The doped polycrystalline silicon may have a high doping concentration, e.g. larger than 10¹⁹ cm⁻³ or even larger than 10²¹ cm⁻³, for achieving lowering of the resistance between a gate pad and the trench gate electrode, for example.

For example, a top side of a third portion of the trench gate electrode may be arranged below the first surface at a vertical distance from the first surface. The second portion of the trench gate electrode may be arranged, along the first lateral direction, between the first portion of the trench gate electrode and the third portion of the trench gate electrode. The vertical distance from the top side of the first portion to the first surface may be equal to the vertical distance from the top side of the third portion to the first surface, e.g. when concurrently forming recesses in the trench gate electrode by an etch process.

For example, the trench field structure may include a trench field dielectric and a trench field electrode. A thickness of the trench field dielectric may be larger than a thickness of the trench gate dielectric. A top side of a first portion of the trench field electrode may be arranged below the first surface at a vertical distance from the first surface. This exemplary arrangement of the first portion may allow for a beneficial reduction of the electric field strength at the edge of the mesa region adjoining the trench field structure. This may allow for improving the reliability of the device by improving the electric breakdown strength of the device.

For example, the first portion of the trench field electrode may adjoin the trench field dielectric along the first lateral direction. The first lateral direction may be directed from the source region to the drain region. Thus, the first portion of the trench field electrode may be arranged outward at a side toward the drain region, for example. This exemplary arrangement of the first portion may allow for a beneficial reduction of the electric field strength at the edge of the mesa region adjoining the trench field structure. This may allow improve the reliability of the device by increasing the electric breakdown strength of the device.

Details described with respect to the exemplary FETs above, e.g. materials, dimensions, configurations, likewise apply to the exemplary FETs described further below.

Another example of the present disclosure relates to a further field effect transistor, FET. The FET includes a transistor cell in a semiconductor substrate having a first surface. The transistor cell includes a source region at the first surface of the semiconductor substrate. The transistor cell further includes a drain region spaced from the source region along a first lateral direction. The transistor cell further includes a trench gate structure arranged, along the first lateral direction, between the source region and the drain region. The transistor cell further includes a trench field structure arranged, along the first lateral direction, between the trench gate structure and the drain region. The trench field structure includes a trench field dielectric and a trench field electrode. A top side of a first portion of the trench field electrode may be arranged below the first surface at a vertical distance from the first surface.

This exemplary vertical arrangement of the top side of the first portion of the trench field electrode may allow for a beneficial reduction of the electric field strength at the edge of the mesa region adjoining the trench field structure. This may allow for improving the reliability of the device by improving the electric breakdown strength of the device.

For example, the vertical distance of the first portion of the trench field electrode from the first surface may have a value in a range from 50 nm to 500 nm.

For example, the first portion of the trench field electrode may adjoin the trench field dielectric along the first lateral direction. The first lateral direction may be directed from the source region to the drain region. Thus, the first portion of the trench field electrode may be arranged outward at a side toward the drain region, for example. This exemplary arrangement of the first portion may allow for a beneficial reduction of the electric field strength at the edge of the mesa region adjoining the trench field structure. This may allow for improving the reliability of the device by increasing the electric breakdown strength of the device.

For example, a second portion of the trench field electrode may vertically extend at least up to the first surface. The second portion of the trench field electrode may be electrically connected to a field electrode interconnection line extending along a second lateral direction. The second lateral direction may be perpendicular to the first lateral direction. The second lateral direction may be a lateral direction along which a device width is measured, for example.

For example, the second portion of the trench field electrode may have a lateral distance, along the first lateral direction, from the drain region that has a value larger than 25% of an extension of the trench field electrode along the first lateral direction. This value range may allow for a beneficial reduction of the electric field strength at the edge of the mesa region adjoining the trench field structure.

For example, a top side of a third portion of the trench field electrode may be arranged below the first surface of the semiconductor substrate at a vertical distance from the first surface. The second portion of the trench field electrode may be arranged, along the first lateral direction, between the third portion of the trench field electrode and the first portion of the trench field electrode. The vertical distance from the top side of the first portion to the first surface may be equal to the vertical distance from the top side of the third portion to the first surface, e.g. when concurrently forming recesses in the trench field electrode by an etch process.

For example, the FET may further include an intermediate dielectric arranged between the first surface of the semiconductor substrate and the field electrode interconnection line. The intermediate dielectric may have a larger thickness than the trench field dielectric.

For example, the trench gate structure may include a trench gate dielectric and a trench gate electrode. A top side of a first portion of the trench gate electrode may be arranged below the first surface at a vertical distance from the first surface of the semiconductor substrate. By arranging the first portion of the trench gate electrode below the first surface, device reliability may be improved by suppressing or avoiding undesired generation of an inversion channel at the corner of the trench gate structure. Furthermore, a leakage current caused by the inversion channel may be avoided or at least reduced. The inversion channel at the corner may have a smaller threshold voltage compared to the device channel at the sidewall and the corruption of the current voltage characteristic by turn-on of the channel at the corner may thus be suppressed or avoided when arranging the first portion of the trench gate electrode below the first surface.

For example, the trench gate dielectric may adjoin the first portion of the trench gate electrode along the first lateral direction. Thus, the first portion of the trench gate electrode may be arranged outward at a side toward the source region, for example. This exemplary arrangement of the first portion may allow for a beneficial suppression of channel turn-on in the corners of the trench gate structure at a side of the source region, for example.

For example, the FET may further include a body region adjoining a bottom side and each of opposite sidewalls of the trench gate structure. The body region may have a conductivity type different from the source region. The body region may have a larger distance, along the first lateral direction, from the drain region than the trench gate structure. For example, the body region may adjoin, e.g. at least part of, the bottom side of the trench gate structure. For example, the body region may adjoin the, e.g. at least part of, the bottom side of the trench gate structure and, e.g. at least part of, opposite sidewalls of the trench gate structure. Thereby, a channel region may be formed at the opposite sidewalls and at the bottom side of the trench gate structure. Along the first lateral direction, the body region may adjoin to more than 60%, or more than 70%, or more than 80%, or more than 90% of a lateral extension of the trench gate structure at the bottom side along the first lateral direction.

For example, the source region may adjoin a body contact region along the second lateral direction. The second lateral direction may be perpendicular to the first lateral direction. In a transistor cell array including a plurality of the transistor cells, the source and body contact regions may be alternately arranged along the second lateral direction, for example.

Details with respect to structure, or function, or technical benefit of features described above with respect to a semiconductor device such as a FET likewise apply to the illustrated FETs described further below with respect to the figures.

The description and drawings merely illustrate the principles of the disclosure. Furthermore, all examples recited herein are principally intended expressly to be only for illustrative purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

In the following, further examples of field effect transistors, FETs, are explained in connection with the accompanying drawings. Functional and structural details described with respect to the examples above shall likewise apply to the exemplary embodiments illustrated in the figures and described further below.

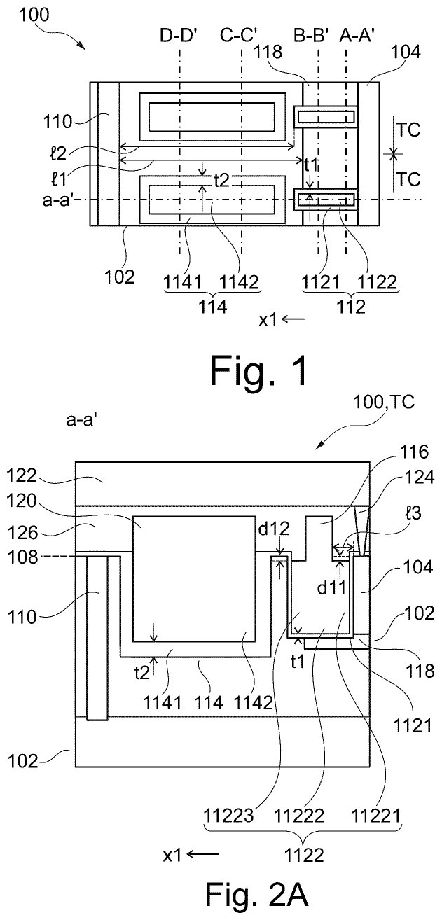

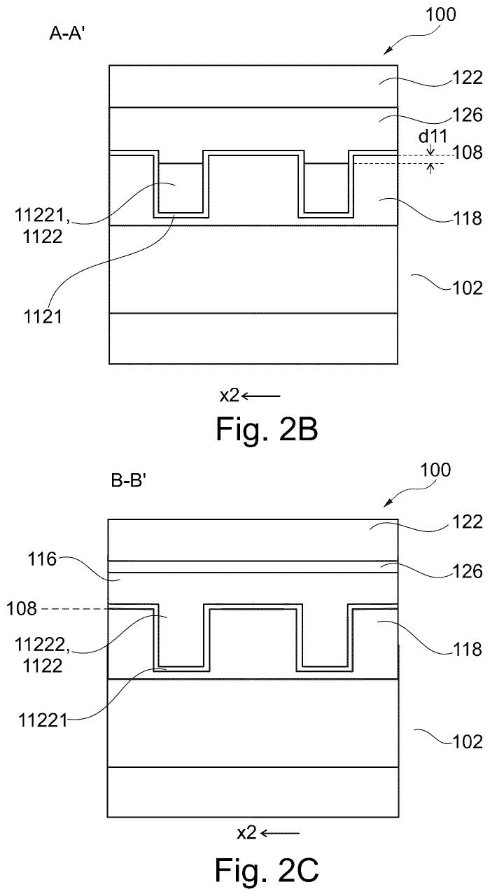

FIG. 1 schematically and exemplarily shows a top view of a part of transistor cells TC of a FET 100. FIG. 2A schematically and exemplarily shows a cross-sectional view along line a-a′ of FIG. 1. FIG. 2B schematically and exemplarily shows a cross-sectional view along line A-A′ of FIG. 1. FIG. 2C schematically and exemplarily shows a cross-sectional view along line B-B′ of FIG. 1.

Referring to FIGS. 1, 2A, 2B and 2C, each transistor cell TC is formed in a semiconductor substrate 102.

At a first surface 108 of the semiconductor substrate 102, an n⁺-doped source region 104 is formed. A drain region 110 is spaced from the source region 104 along a first lateral direction x1. The drain region 110 may be electrically connected at a second surface of the semiconductor substrate 102 opposite to the first surface 108 or at the first surface 108 (not illustrated). In FIG. 2A and further figures described below, the drain region 110 extends into a portion of the semiconductor substrate 102. The drain region 110 is electrically connected via the second surface of the semiconductor substrate 102 (not illustrated).

The first surface 108 is a surface of the semiconductor substrate 102 where e.g. an interface between a doped region in the semiconductor substrate 102, e.g. the source region 104, and a contact to the doped region, e.g. a contact plug or line 124 illustrated in FIG. 2A, is located.

A trench gate structure 112 is arranged between the source region 104 and the drain region 110 along the first lateral direction x1. A trench gate dielectric 1121 of the trench gate structure 112 electrically isolated a trench gate electrode 1122 of the trench gate structure 112 from a surrounding part of the semiconductor substrate 102.

A p-doped body region 118 adjoins opposite sidewalls (see e.g. FIG. 1) and a bottom side (see e.g. FIG. 2A) of the trench gate structure 112. Thereby, a channel region can be formed a at the opposite sidewalls and at the bottom side of the trench gate structure 112. The body region 118 has a distance 11, along the first lateral direction x1, from the drain region 110 that is larger than a distance 12 of the trench gate structure 112 from the drain region 110.

Each of the transistor cells TC further includes a trench field structure 114. The trench field structure 114 is arranged between the trench gate structure 112 and the drain region 110 along the first lateral direction x1. A thickness t2 of a trench field dielectric 1141 is larger than a thickness t1 of a trench gate dielectric 1121.

Referring to FIG. 2A, the trench gate electrode 1122 includes a first portion 11221. The first portion 11221 is a portion located toward the source region 104. Thus, the first portion 11221 is a portion of the trench gate electrode 1122 that faces the source region 104.

The trench gate electrode 1122 further includes a second portion 11222 that vertically extends at least up to the first surface 108 of the semiconductor substrate 102.

Referring to FIGS. 2A and 2C, the second portion 11222 of the trench gate structure 1122 is electrically connected to a gate interconnection line 116. The gate interconnection line 116 extends along a second lateral direction x2 that runs perpendicular to the first lateral direction x1. The second portion 11222 of the trench gate electrode 1122 has a lateral distance 13, along the first lateral direction x1, from the source region 104.

Referring to FIG. 2A, the trench gate electrode 1122 further includes a third portion 11223. The second portion 11222 of the trench gate electrode 1122 is arranged, along the first lateral direction x1, between the first portion 11221 of the trench gate electrode 1122 and the third portion 11223 of the trench gate electrode 1122.

A top side of the first portion 11221 of the trench gate electrode 1122 is arranged below the first surface 108 at a vertical distance d11 from the first surface 108. A top side of the third portion 11223 of the trench gate electrode 1122 is arranged below the first surface 108 at a vertical distance d12 from the first surface 108. For example, d11 may be equal to d12, e.g. when concurrently forming recesses in the trench gate electrode. The third portion 11223 of the trench gate electrode 1122 may also be omitted. In this case, the trench gate electrode 1122 may be formed by the first and second portions 11221, 11222, for example.

An electric contact to the body region 118 may be formed in a body contact region by interrupting the source region 104 along the second lateral direction x2, for example (not illustrated). The electric contact from a source electrode 122 to the source region 104 (and the body region 118) is provided via the contact plug or line 124 extending through an intermediate dielectric 126.

A trench field electrode 1142 of the trench field structure 114 is electrically connected to a field electrode interconnection line 120.

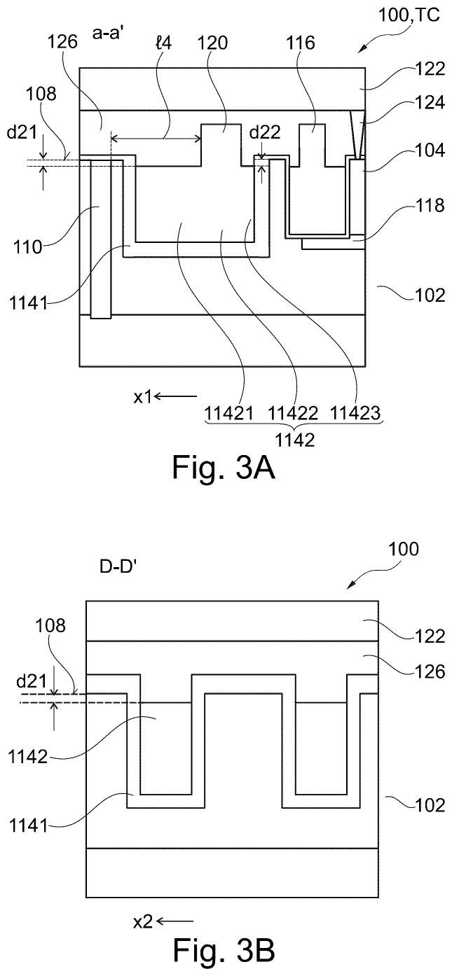

Other examples of cross-sectional views are illustrated in FIGS. 3A to 3C. FIG. 3A schematically and exemplarily shows another cross-sectional view along line a-a′ of FIG. 1. FIG. 3B schematically and exemplarily shows a cross-sectional view along line D-D′ of FIG. 1. FIG. 3C schematically and exemplarily shows a cross-sectional view along line C-C′ of FIG. 1.

Referring to FIG. 3A, the trench field electrode 1142 includes a first portion 11421. The first portion 11421 is a portion located toward the drain region 110. Thus, the first portion 11421 is a portion of the trench field electrode 1142 that faces the drain region 110.

The trench field electrode 1142 further includes a second portion 11422 that vertically extends at least up to the first surface 108 of the semiconductor substrate 102.

Referring to FIGS. 3A and 3C, the second portion 11422 of the trench field structure 1142 is electrically connected to a field electrode interconnection line 120. The field electrode interconnection line 120 extends along the second lateral direction x2 that runs perpendicular to the first lateral direction x1. The second portion 11422 of the trench field electrode 1142 has a lateral distance 14, along the first lateral direction x1, from the drain region 110.

Referring to FIG. 3A, the trench field electrode 1142 further includes a third portion 11423. The second portion 11422 of the trench field electrode 1142 is arranged, along the first lateral direction x1, between the first portion 11421 of the trench field electrode 1142 and the third portion 11423 of the trench field electrode 1422.

Referring to FIGS. 3A and 3B, a top side of the first portion 11421 of the trench field electrode 1142 is arranged below the first surface 108 at a vertical distance d21 from the first surface 108. A top side of the third portion 11423 of the trench field electrode 1142 is arranged below the first surface 108 at a vertical distance d22 from the first surface 108. For example, the distance d21 may be equal to the distance d22, e.g. when concurrently forming recesses in the trench field electrode. The third portion 11423 of the trench field electrode 1142 may also be omitted. In this case, the trench field electrode 1142 may be formed by the first and second portions 11421, 11422, for example. Referring to FIG. 3C, an intermediate dielectric 121 is arranged between the first surface 108 of the semiconductor substrate 102 and the field electrode interconnection line 120. The intermediate dielectric 121 has a larger thickness t3 than the trench field dielectric 1141.

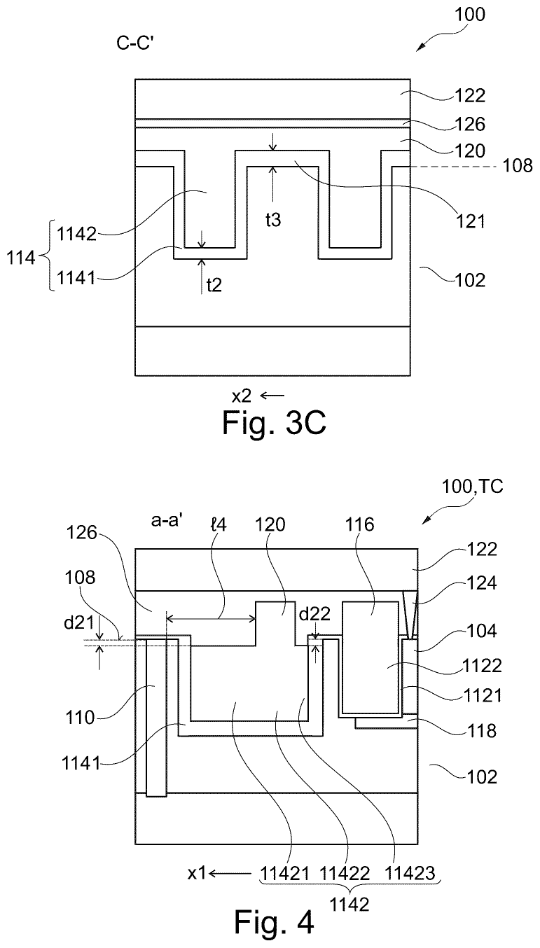

A further example of a cross-sectional view along line a-a′ of FIG. 1 is illustrated in the FIG. 4.

Similar to the example of FIG. 3A, the example of FIG. 4 includes recessed portion(s) in the trench field electrode 1142, i.e. the first and third portions 11421, 11423. However, a recessed portion is omitted in the trench gate electrode 1122.

The aspects and features mentioned and described together with one or more of the previously described examples and figures, may as well be combined with one or more of the other examples in order to replace a like feature of the other example or in order to additionally introduce the feature to the other example.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A field effect transistor (FET) comprising a transistor cell in a semiconductor substrate having a first surface, wherein the transistor cell comprises:
a source region at the first surface of the semiconductor substrate;
a drain region spaced from the source region along a first lateral direction;
a trench gate structure arranged, along the first lateral direction, between the source region and the drain region, wherein the trench gate structure includes a trench gate dielectric and a trench gate electrode;
a trench field structure arranged, along the first lateral direction, between the trench gate structure and the drain region, and
wherein a top side of a first portion of the trench gate electrode is arranged below the first surface at a vertical distance from the first surface.

2. The FET of claim 1, wherein the vertical distance is a range from 50 nm to 500 nm.

3. The FET of claim 1, wherein the trench gate dielectric adjoins the first portion of the trench gate electrode along the first lateral direction.

4. The FET of claim 1, wherein a second portion of the trench gate electrode vertically extends at least up to the first surface of the semiconductor substrate and is electrically connected to a gate interconnection line extending along a second lateral direction, and wherein the second lateral direction is perpendicular to the first lateral direction.

5. The FET of claim 4, wherein the second portion of the trench gate electrode has a lateral distance, along the first lateral direction, from the source region that has a value in a range from 100 nm to 500 nm.

6. The FET of claim 4, wherein the trench gate electrode and the gate interconnection line comprise doped polycrystalline silicon.

7. The FET of claim 4, wherein a top side of a third portion of the trench gate electrode is arranged below the first surface at a vertical distance from the first surface, and wherein the second portion of the trench gate electrode is arranged, along the first lateral direction, between the first portion of the trench gate electrode and the third portion of the trench gate electrode.

8. The FET of claim 1, wherein the trench field structure includes a trench field dielectric and a trench field electrode, wherein a thickness of the trench field dielectric is larger than a thickness of the trench gate dielectric, and wherein a top side of a first portion of the trench field electrode is arranged below the first surface at a vertical distance from the first surface.

9. The FET of claim 8, wherein the first portion of the trench field electrode adjoins the trench field dielectric along the first lateral direction.

10. The FET of claim 1, further comprising a body region adjoining a bottom side and each of opposite sidewalls of the trench gate structure, wherein the body region has a conductivity type different from the source region, and wherein the body region has a larger distance, along the first lateral direction, from the drain region than the trench gate structure.

11. A field effect transistor (FET) comprising a transistor cell in a semiconductor substrate having a first surface, wherein the transistor cell comprises:
a source region at the first surface of the semiconductor substrate;
a drain region spaced from the source region along a first lateral direction;
a trench gate structure arranged, along the first lateral direction, between the source region and the drain region;
a trench field structure arranged, along the first lateral direction, between the trench gate structure and the drain region, wherein the trench field structure includes a trench field dielectric and a trench field electrode, and
wherein a top side of a first portion of the trench field electrode is arranged below the first surface at a vertical distance from the first surface.

12. The FET of claim 11, wherein the vertical distance is in a range from 50 nm to 500 nm.

13. The FET of claim 11, wherein the first portion of the trench field electrode adjoins the trench field dielectric along the first lateral direction.

14. The FET of claim 11, wherein a second portion of the trench field electrode vertically extends at least up to the first surface and is electrically connected to a field electrode interconnection line extending along a second lateral direction, and wherein the second lateral direction is perpendicular to the first lateral direction.

15. The FET of claim 14, wherein the second portion of the trench field electrode has a lateral distance, along the first lateral direction, from the drain region that has a value larger than 25% of an extension of the trench field electrode along the first lateral direction.

16. The FET of claim 14, wherein a top side of a third portion of the trench field electrode is arranged below the first surface of the semiconductor substrate at a vertical distance from the first surface, and wherein the second portion of the trench field electrode is arranged, along the first lateral direction, between the third portion of the trench field electrode and the first portion of the trench field electrode.

17. The FET of claim 14, further comprising an intermediate dielectric arranged between the first surface of the semiconductor substrate and the field electrode interconnection line, wherein the intermediate dielectric has a larger thickness than the trench field dielectric.

18. The FET of claim 11, wherein the trench gate structure includes a trench gate dielectric and a trench gate electrode, and wherein a top side of a first portion of the trench gate electrode is arranged below the first surface at a vertical distance from the first surface of the semiconductor substrate.

19. The FET of claim 18, wherein the trench gate dielectric adjoins the first portion of the trench gate electrode along the first lateral direction.

20. The FET of claim 11, further comprising a body region adjoining a bottom side and each of opposite sidewalls of the trench gate structure, wherein the body region has a conductivity type different from the source region, and wherein the body region has a larger distance, along the first lateral direction, from the drain region than the trench gate structure.
